(19) United States
(12) Patent Application Publication
(10) Pub. No.: US 2024/0248389 A1
(43) Pub. Date: Jul. 25, 2024

(54) APPARATUS FOR FABRICATING BLANK MASK AND METHOD OF FABRICATING THE SAME

(71) Applicant: SK enpulse Co., Ltd., Gyeonggi-do (KR)

(72) Inventors: Tae Wan KIM, Seoul (KR); Geon Gon LEE, Seoul (KR); Seong Yoon KIM, Seoul (KR)

(21) Appl. No.: 18/412,602

(22) Filed: Jan. 15, 2024

(30) Foreign Application Priority Data
Jan. 19, 2023 (KR) 10-2023-0007856

(51) Int. Cl. G03F 1/32; G03F 1/38; G03F 1/82

(52) U.S. Cl. CPC G03F 1/32; G03F 1/38; G03F 1/82

(57) ABSTRACT

Disclosed is an apparatus for fabricating a blank mask, the apparatus including: a chamber; and a rotatable chuck placed inside the chamber, wherein the rotatable chuck includes: a support part configured to support an optical substrate placed on the support part; and a guide part disposed on a side of the optical substrate and connected to the support part, wherein an interval between the guide part and a side surface of the optical substrate is greater than 0 mm and less than 1 mm.

### CROSS-REFERENCE TO RELATED APPLICATION

The present application claims priority under 35 U.S.C. 119(a) to Korean patent application number 10-2023-0007856 filed on Jan. 19, 2023, which is incorporated herein by reference in its entirety.

### TECHNICAL FIELD

Embodiments relate to an apparatus for fabricating a blank mask and a method of fabricating the same.

### BACKGROUND ART

Due to the high integration of semiconductor devices, there is a demand for refinement of circuit patterns of semiconductor devices. Thereby, the importance of lithography technology, a technology that develops circuit patterns on the surface of a wafer using a photomask, is attracting more attention.

To develop refined circuit patterns, a shorter wavelength of the exposure light source used in an exposure process is required. As examples of exposure light sources recently used, there are ArF excimer laser (wavelength: 193 nm), and the like.

Meanwhile, a photomask includes a binary mask, a phase shift mask, and the like.

A binary mask includes a light-shielding layer pattern formed on a light-transmissive substrate. On the surface, where patterns are formed, of a binary mask, a light transmission part excluding a light-shielding layer transmits exposure light, and a light-shielding part including a light-shielding layer blocks exposure light, exposing a pattern on a resist film of a wafer surface. Meanwhile, problems may occur in the fine pattern phenomenon due to light diffraction that occurs at the edges of a light transmission part during an exposure process as the pattern of a binary mask becomes finer.

As examples of a phase shift mask, there are a Levenson-type mask, an outrigger-type mask, and a half tone-type mask. Among these, a half tone-type phase shift mask has a pattern, which is made of a semi-transmissive film, formed on a light-transmissive substrate 20. On the patterned surface of the half tone-type phase shift mask, a light transmission part excluding a semi-transmissive layer transmits exposure light, and a semi-transmissive part including a semi-transmissive layer transmits attenuated exposure light. The attenuated exposure light has a phase difference compared to the exposure light that passed through the light transmission part. Accordingly, diffracted light occurring at the edge of the light transmission part is canceled out by exposure light transmitted through the semi-transmissive part, so that the phase shift mask can form a more elaborate fine pattern on a wafer surface.

Related documents are as follows:
Korean Patent Application Publication No. 10-2012-0057488
Korean Patent Application Publication No. 10-2014-0130420

### TECHNICAL PROBLEM

Therefore, the present invention has been made in view of the above problems, and one object of the present invention is providing an apparatus for fabricating a blank mask that can provide a photomask having low defect occurrence, improved number of uses, and high precision and a method of fabricating the blank mask

### SUMMARY OF THE INVENTION

In accordance with an aspect of the present invention, the above and other objects can be accomplished by an apparatus for fabricating a blank mask, the apparatus including: a chamber; and a rotatable chuck placed inside the chamber, wherein the chuck includes: a support part configured to support an optical substrate placed on the support part; and a guide part disposed on a side of the optical substrate and connected to the support part, wherein an interval between the guide part and a side surface of the optical substrate is greater than 0 mm and less than 1 mm.

In the apparatus for fabricating a blank mask according to an embodiment, the apparatus may further include a by-product removal part disposed in a space between the side surface of the optical substrate and the guide part and configured to remove process by-products flowing into the space between the side surface of the optical substrate and the guide part.

In the apparatus for fabricating a blank mask according to an embodiment, the apparatus may further include a vacuum part for applying vacuum pressure to the by-product removal part, when the by-product removal part suctions the process by-products.

In the apparatus for fabricating a blank mask according to an embodiment, the by-product removal part may include a plurality of spaced apart holes for suctioning the process by-products when the holes are connected to the vacuum part.

In the apparatus for fabricating a blank mask according to an embodiment, the holes may have a diameter of about 0.5 mm to about 2 mm, and an interval between the holes may be about 10 mm to 100 mm, and wherein the holes are disposed at an edge of the support part disposed in the space between the side surface of the optical substrate and the guide part.

In the apparatus for fabricating a blank mask according to an embodiment, a height difference between a top surface of the guide part and a top surface of the optical substrate when the optical substrate is positioned on the support part may be less than 1 mm.

In the apparatus for fabricating a blank mask according to an embodiment, the by-product removal part may be disposed to correspond to a corner region where the side surface of the optical substrate and a lower surface of the optical substrate meet.

In an embodiment, the by-product removal part is disposed at an edge region of a receiving part of the support part adjacent to an edge region of the optical substrate.

In the apparatus for fabricating a blank mask according to an embodiment, the by-product removal part may suction the process by-products and discharge the process by-products outside of the chamber.

In accordance with another aspect of the present invention, provided is a method of fabricating a blank mask, the method including: forming an optical substrate comprising a light-shielding film on a light transmissive substrate; seating a chuck on the optical substrate including the light-shielding film formed thereon; forming a photoresist layer on the light-shielding film; and removing process by-products, generated in the process of forming the photoresist layer, from a space between a side surface of the optical substrate and the chuck.

In the method of fabricating the blank mask according to an embodiment, the forming of the photoresist layer may include: dropping a photoresist composition on the light-shielding film; and rotating the optical substrate, wherein the rotating of the optical substrate is performed simultaneously with the removing of the process by-products.

In the method of fabricating the blank mask according to an embodiment, the chuck may include: a support part disposed under the optical substrate; a guide part connected to the support part and disposed on a side of the optical substrate; and a by-product removal part configured to suction and discharge process by-products by vacuum pressure.

In the method of fabricating the blank mask according to an embodiment, the process by-products may be fine particles derived from the photoresist resin composition, and wherein the by-product removal part is disposed at an edge region of a receiving part of the support part adjacent to an edge region of the optical substrate.

In the method of fabricating the blank mask according to an embodiment, the fine particles may have a diameter of about 1 μm to about 10 μm.

In the method of fabricating the blank mask according to an embodiment, the optical substrate may rotate at a speed of about 500 rpm to about 7000 rpm, and an exhaust speed of the by-product removal part may be about 1 ml/s to about 100 ml/s.

In the method of fabricating the blank mask according to an embodiment, an interval between the guide part and the side surface of the optical substrate may be greater than 0 mm and less than 1 mm.

In the method of fabricating the blank mask according to an embodiment, the by-product removal part may include holes configured to penetrate the chuck and connect with a vacuum part.

In the method of fabricating the blank mask according to an embodiment, the holes may have a diameter of about 0.5 mm to about 2 mm, and an interval between the holes may be about 10 mm to 100 mm.

In the method of fabricating the blank mask according to an embodiment, the vacuum pressure may be applied by a vacuum part connected to the holes, and the vacuum part may discharge process by-products flowing through the holes.

In the method of fabricating the blank mask according to an embodiment, a top surface of the optical substrate may be higher than a top surface of the guide part, wherein a height difference between the top surface of the guide part and the top surface of the optical substrate is about 0.1 mm to about 0.5 mm. According to an embodiment, an apparatus for fabricating a blank mask, the apparatus comprises a vacuum sealed chamber; and a rotatable chuck placed in a vacuum sealing arrangement inside the chamber, the chuck comprising a support part and a guide part connected to the support part, the support part and the guide part forming a receiving part configured to receive an optical substrate leaving an interval between the guide part and a side surface of the optical substrate of greater than 0 mm and less than 1 mm, wherein the support part extends both inside and outside of the chamber, a plurality of holes formed in the support part in a space between the side surface of the optical substrate and the guide part and configured to remove process by-products flowing into the space between the side surface of the optical substrate and the guide part, and a vacuum part for applying vacuum pressure to the plurality of holes for suctioning and discharging the process by-products.

### ADVANTAGEOUS EFFECTS

An apparatus for fabricating a blank mask according to an embodiment can appropriately control an interval between a guide part and an optical substrate. In particular, in the apparatus for fabricating a blank mask according to an embodiment, the interval between the guide part and the optical substrate may be greater than 0 mm and less than 1 mm.

Accordingly, the apparatus for fabricating a blank mask according to an embodiment can prevent process by-products from flowing between the guide part and the optical substrate. Accordingly, the apparatus for fabricating a blank mask according to an embodiment can prevent contamination of a side surface of the optical substrate and a lower surface of the optical substrate.

In addition, the apparatus for fabricating a blank mask according to an embodiment can include a by-product removal part disposed under a space between the guide part and a side surface of the optical substrate. The by-product removal part can remove process by-products flowing into the space between the guide part and the side surface of the optical substrate.

In particular, the by-product removal part can suck the process by-products through vacuum pressure. Accordingly, the by-product removal part can easily remove fine particle-type by-products flowing between the guide part and the side surface of the optical substrate.

In particular, since the by-product removal part is disposed to correspond to a corner where the side surface of the optical substrate and the lower surface thereof meet, it can efficiently remove the process by-products.

Accordingly, the apparatus for fabricating a blank mask according to an embodiment can minimize contamination of the process by-products. In particular, the blank mask according to an embodiment can prevent the process by-products from contaminating the side and lower surfaces of the optical substrate.

These and other features and advantages of the present invention will become apparent from the following detailed description in conjunction with the following drawings.

### DESCRIPTION OF DRAWINGS

FIG. 1 is a schematic view illustrating an apparatus for fabricating a blank mask according to an embodiment.

FIG. 2 is a perspective view illustrating a chuck according to an embodiment.

FIG. 3 illustrates an upper surface of the chuck according to an embodiment.

FIG. 4 is a sectional view illustrating a cross-section of the chuck.

FIG. 5 illustrates an enlarged cross-sectional view of part A of FIG. 4.

FIG. 6 illustrates a process by which process by-products are removed according to an embodiment.

FIG. 7 is a sectional view illustrating a cross-section of an optical substrate according to an embodiment.

FIG. 8 is a sectional view illustrating a cross-section of an optical substrate according to another embodiment.

FIG. 9 is a sectional view illustrating a cross-section of the optical substrate according to still another embodiment.

FIG. 10 is a sectional view illustrating a cross-section of a blank mask according to an embodiment.

FIG. 11 is a sectional view illustrating a cross-section of a photomask according to an embodiment.

### DETAILED DESCRIPTION

Hereinafter, embodiments will be described in detail such that those skilled in the art can easily implement them. However, the embodiments may be implemented in various different forms and are not limited to embodiments described herein.

The terms “about,” “substantially,” and the like used in this specification are used to mean at or close to a presented numerical value when manufacturing and material tolerances inherent in stated meaning are presented, and are used to better convey the scope of the present invention in which precise or absolute figures are mentioned to aid understanding of the embodiments.

Throughout this specification, the term “a combination thereof” included in the Markush format expression refers to a mixture or combination of one or more elements selected from the group consisting of components described in the Markush format expression, and to include one or more selected from the group consisting of the components.

Throughout this specification, the expression “A and/or B” means “A, B, or A and B”.

Throughout this specification, terms such as “first”, “second” or “A” and “B” are used to distinguish the same terms from each other unless otherwise specified.

In this specification, “B is located on A” means “B is located on A” or “B is located over A with another layer located therebetween”, and is not interpreted as limited to B being positioned in contact with the surface of A.

In this specification, singular expressions are interpreted to include singular or plural as interpreted in context, unless otherwise specified.

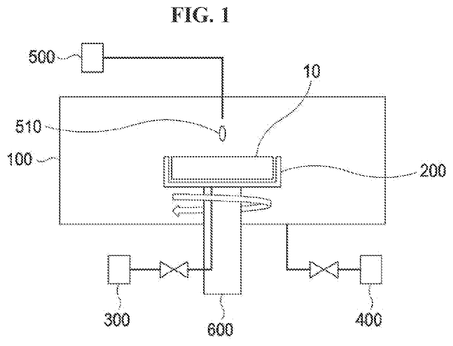

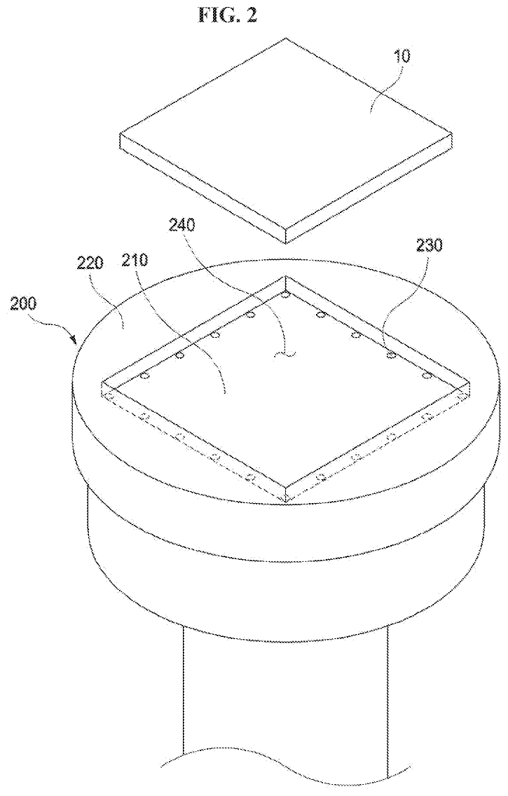

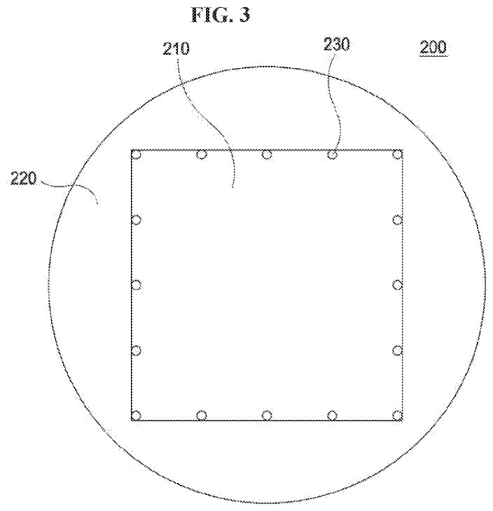

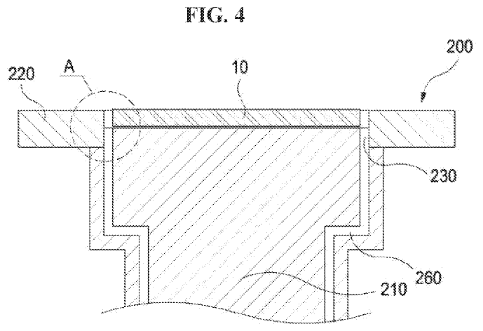

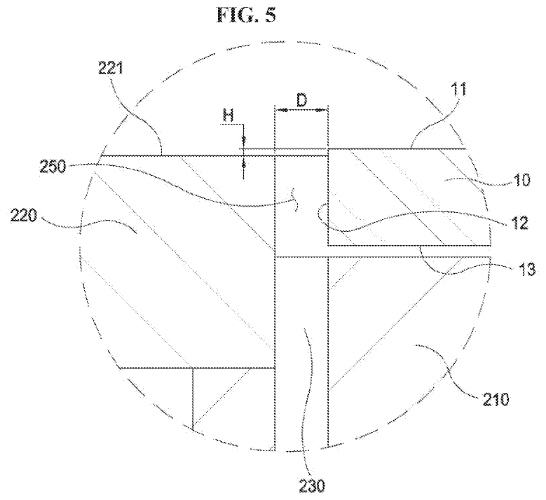

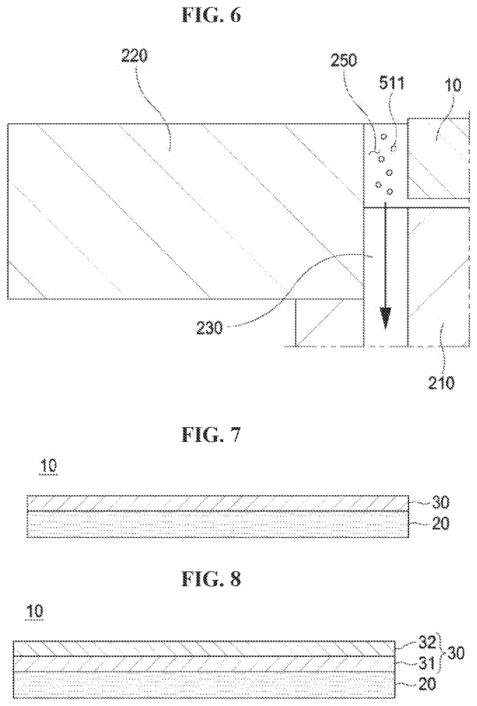

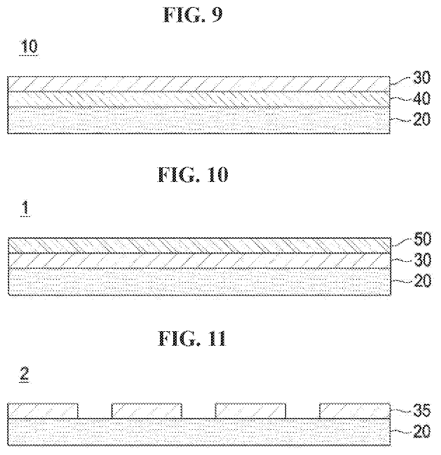

FIG. 1 is a schematic view illustrating an apparatus for fabricating a blank mask according to an embodiment. FIG. 2 is a perspective view illustrating a chuck according to an embodiment. FIG. 3 illustrates an upper surface of the chuck according to an embodiment. FIG. 4 is a sectional view illustrating a cross-section of the chuck. FIG. 5 illustrates an enlarged cross-sectional view of part A of FIG. 4. FIG. 6 illustrates a process by which process by-products are removed according to an embodiment. FIG. 7 is a sectional view illustrating a cross-section of an optical substrate according to an embodiment. FIG. 8 is a sectional view illustrating a cross-section of an optical substrate according to another embodiment. FIG. 9 is a sectional view illustrating a cross-section of the optical substrate according to still another embodiment. FIG. 10 is a sectional view illustrating a cross-section of a blank mask according to an embodiment. FIG. 11 is a sectional view illustrating a cross-section of a photomask according to an embodiment.

Referring to FIG. 1, the apparatus for fabricating a blank mask according to an embodiment includes a chamber 100, a chuck 200, a vacuum part 300, an exhaust part 400 and a photoresist resin composition supply part 500.

The chamber 100 contains the chuck 200. The chamber 100 may contain an optical substrate 10 for fabricating a blank mask. The inside of the chamber 100 may be isolated from the outside. The interior of the chamber 100 may be sealed. The pressure inside the chamber 100 may be lower than atmospheric pressure.

In addition, the chamber 100 may include a door or cover that can be opened or closed. The chamber 100 may be heated to a desired temperature. For example, a heater that can control the temperature inside the chamber 100 may be provided in the chamber 100.

Referring to FIGS. 2 to 6, the chuck 200 includes a support part 210, a guide part 220 and a by-product removal part 230.

The support part 210 may support the guide part 220 and the by-product removal part 230. The support part 210 supports the optical substrate 10. The support part 210 may be disposed under the optical substrate 10.

The support part 210 may temporarily fix the optical substrate 10. The support part 210 may temporarily fix the optical substrate 10 by vacuum pressure or electrostatic force.

The guide part 220 may be connected to the support part 210. The guide part 220 may be formed integrally with the support part 210. The guide part 220 may be disposed on a side surface 12 of the optical substrate 10. The guide part 220 may surround the side surface 12 of the optical substrate 10.

Due to the support part 210 and the guide part 220, a receiving part 240 for accommodating the optical substrate 10 may be formed. That is, the support part 210 may be disposed on a lower surface 13 of the optical substrate 10, and the guide part 220 may be disposed on the side surface 12 of the optical substrate 10, thereby constituting the receiving part 240.

The receiving part 240 may correspond to the planar shape of the optical substrate 10. The planar shape of the receiving part 240 may be substantially similar to the planar shape of the optical substrate 10. For example, the planar shape of the optical substrate 10 may be square, and the planar shape of the receiving part 240 may also be square. However, the shape of the optical substrate 10 is not limited to the planar shape, and may have different shapes such as circular planar shape.

The outline of the guide part 220 may have a circular shape. The guide part 220 and the support part 210 may have a circular shape.

The by-product removal part 230 may be formed on the support part 210. The by-product removal part 230 may be formed on the guide part 220. The by-product removal part 230 may be formed on a part where the support part 210 and the guide part 220 meet. The by-product removal part 230 may be formed over the support part 210 and the guide part 220.

The by-product removal part 230 may be formed in a region corresponding to an edge part of the optical substrate 10. The by-product removal part 230 may be formed along the edge part of the support part 210.

The by-product removal part 230 may include a plurality of holes that can spray gas or suction (draw and remove) gas. The holes may extend downward or laterally. The diameter of the holes may be about 0.5 mm to about 2 mm. An interval between the holes may be about 10 mm to 100 mm. The holes may be arranged, for example in a single row at each of the four side edges of the receiving part 240.

The holes may penetrate the chuck 200. The holes may penetrate the support part 210.

The by-product removal part 230 may be disposed under a space 250 between the guide part 220 and the side surface 12 of the optical substrate 10. The by-product removal part 230 may be disposed to correspond to a region 250 between an inner side surface of the guide part 220 and the side surface 12 of the optical substrate 10.

The guide part 220 and the side surface 12 of the optical substrate 10 may be spaced apart from each other by a certain interval. A distance D between the inner side surface of the guide part 220 and the side surface 12 of the optical substrate 10 may be about 0.01 mm to about 1 mm. An interval D between the guide part 220 and the side surface 12 of the optical substrate 10 may be less than about 1 mm. The interval D between the guide part 220 and the side surface 12 of the optical substrate 10 may be greater than about 0.01 mm and less than about 0.5 mm. The interval D between the guide part 220 and the side surface 12 of the optical substrate 10 may be greater than about 0.01 mm and less than about 0.2 mm. The interval D between the guide part 220 and the side surface 12 of the optical substrate 10 may be greater than about 0.01 mm and less than about 0.15 mm.

Since the guide part 220 and the side surface 12 of the optical substrate 10 have the above-described interval D, the inflow of the process by-products 511 into the space 250 between the guide part 220 and the optical substrate 10 may be suppressed. In particular, since the guide part 220 and the side surface 12 of the optical substrate 10 have the above-described interval D, the apparatus for fabricating a blank mask according to an embodiment may prevent the photoresist composition from permeating between the guide part 220 and the optical substrate 10 or contaminating due to rebounding.

In addition, since the guide part 220 and the side surface 12 of the optical substrate 10 have the above-described interval D, the optical substrate 10 may be easily seated on the support part 210. Since the guide part 220 and the side surface 12 of the optical substrate 10 have the above-described interval D, scratches and the like may be prevented when the optical substrate 10 is detached from the support part 210. In particular, since the guide part 220 and the optical substrate 10 are appropriately spaced apart from each other, scratches or cracks that may occur when the optical substrate 10 is mounted on or detached from the support part 210 may be prevented.

In addition, since the holes have the above-described diameter and interval, the by-product removal part 230 may easily remove the process by-products 511 flowing into the space between the guide part 220 and the optical substrate 10.

A top surface 11 of the optical substrate 10 may be higher than a top surface 221 of the guide part 220. That is, the top surface 221 of the guide part 220 may be lower than the top surface 11 of the optical substrate 10.

A height difference “H” between the top surface 221 of the guide part 220 and the top surface 11 of the optical substrate 10 may be less than about 1 mm. A height difference between the top surface 221 of the guide part 220 and the top surface 11 of the optical substrate 10 may be about 0.1 mm to about 0.5 mm. The height difference between the top surface 221 of the guide part 220 and the top surface 11 of the optical substrate 10 may be about 0.1 mm to about 25 mm. The height difference between the top surface 221 of the guide part 220 and the top surface 11 of the optical substrate 10 may be about 0.1 mm to about 0.2 mm.

When a height difference between the top surface 221 of the guide part 220 and the top surface 11 of the optical substrate 10 is the same as the above-described difference, the process by-products 511 may be easily discharged when the optical substrate 10 is spin-coated with a photoresist resin composition.

The by-product removal part 230 may be connected to the vacuum part 300. The by-product removal part 230 may be connected to the vacuum part 300 through a flow path 260. The by-product removal part 230 may receive vacuum pressure generated by the vacuum part 300 through the flow path 260 and the process by-products 511. That is, the process by-products 511 may be removed by the vacuum part 300 through the by-product removal part 230 and the flow path 260.

The process by-products 511 may include fine particles. The fine particles may be formed by scattering of the photoresist resin composition. The diameter of the fine particles may be less than about 10 μm. The diameter of the fine particles may be about 1 μm to about 10 μm.

An exhaust speed of the by-product removal part 230 may be about 1 ml/s to about 100 ml/s. Accordingly, the by-product removal part 230 may easily remove the process by-products 511 included in the space between the guide part 220 and the optical substrate 10.

The vacuum part 300 may be connected to the by-product removal part 230. The vacuum part 300 may be connected to the holes. The vacuum part 300 may be connected to the by-product removal part 230 through the flow path 260. The vacuum part 300 may apply vacuum pressure to the by-product removal part 230. The vacuum part 300 may suck and filter the process by-products 511. The vacuum part 300 may discharge the process by-products 511.

The exhaust part 400 may exhaust gas inside the chamber 100. In addition, the exhaust part 400 may discharge a photoresist composition remaining after being coated on the optical substrate 10. The exhaust part 400 may discharge a photoresist resin composition scattered to the side of the chuck 200.

In addition, the apparatus for fabricating a blank mask according to an embodiment may further include a suction nozzle. The suction nozzle may extend from the exhaust part 400 and may be disposed on one side of the chuck 200. The suction nozzle may suction a photoresist composition scattered laterally from the chuck 200.

The photoresist resin composition supply part 500 may supply a photoresist resin composition 510 to a top surface of the optical substrate 10. The photoresist resin composition 510 may include a spray nozzle disposed in the chamber 100. Through the spray nozzle, the photoresist resin composition 510 may be dropped onto the optical substrate 10. That is, the photoresist resin composition supply part 500 may spray the photoresist resin composition 510 to the top surface of the optical substrate 10.

A spindle motor 600 may be connected to the chuck 200. The spindle motor 600 may rotate the chuck 200 at high speed. The chuck 200 may rotate at a speed of about 500 rpm to about 7000 rpm by the spindle motor 600.

As the chuck 200 rotates, centrifugal force may be applied to the dropped photoresist resin composition, and a photoresist resin composition layer may be formed to a uniform thickness on the optical substrate 10.

The by-product removal part 230 may suck the process by-products 511 through vacuum pressure. Accordingly, the by-product removal part 230 may easily remove the process by-products 511 in the form of fine particles flowing between the guide part 220 and the side surface 12 of the optical substrate 10.

In particular, since the by-product removal part 230 is placed to correspond to a corner where the side surface 12 of the optical substrate 10 and the lower surface 13 thereof meet, the process by-products 511 may be efficiently removed.

Accordingly, the apparatus for fabricating a blank mask according to an embodiment may minimize contamination by the process by-products 511. In particular, a blank mask according to an embodiment may prevent the process by-products 511 from contaminating the side surface 12 of the optical substrate 10 and the lower surface 13 thereof.

The blank mask according to an embodiment may be produced according to the following fabrication process.

First, the optical substrate 10 may be provided. The optical substrate 10 may include a light-transmissive substrate 20; and a light-shielding film 30 placed on the light-transmissive substrate 20.

The light-transmissive substrate 20 may have optical transparency to exposure light. The light-transmissive substrate 20 may have a transmittance of greater than about 85% for exposure light having a wavelength of about 193 nm. The transmittance of the light-transmissive substrate 20 may be greater than about 87%. The transmittance of the light-transmissive substrate 20 may be less than 99.99%. The light-transmissive substrate 20 may include a synthetic quartz substrate. In this case, the light-transmissive substrate 20 may suppress the attenuation of transmitted light.

Since the light-transmissive substrate 20 has surface characteristics such as appropriate flatness and appropriate illuminance, it may suppress distortion of transmitted light.

The light-shielding film 30 may be disposed on a top side of the light-transmissive substrate 20.

The light-shielding film 30 may at least selectively block exposure light incident on a bottom side of the light-transmissive substrate 20.

In addition, when a phase shift film 40, etc. Is disposed between the light-transmissive substrate 20 and the light-shielding film 30 as shown in FIG. 7, the light-shielding film 30 may be used as an etching mask in a process of etching the phase inversion film 40. According to a pattern shape.

The light-shielding film 30 may include a transition metal and at least one of oxygen and nitrogen.

The light-shielding film 30 may include chromium, oxygen, nitrogen and carbon. The content of each element in the entire light-shielding film 30 may vary in the thickness direction. The content of each element in the entire light-shielding film 30 may differ by layer in the case of a multi-layered light-shielding film 30.

The light-shielding film 30 may include chromium in a content of about 44 atom % to about 60 atom %. The light-shielding film 30 may include chromium in a content of about 47 atom % to about 57 atom %.

The light-shielding film 30 may include carbon in a content of about 5 atom % to 30 atom %. The light-shielding film 30 may include carbon in a content of about 7 atom % to about 25% atom %.

The light-shielding film 30 may include nitrogen in a content of about 3 atom % to about 20 atom %. The light-shielding film 30 may include nitrogen in a content of about 5 atom % to about 15 atom %.

The light-shielding film 30 may include oxygen in a content of about 20 atom % to about 45 atom %. The light-shielding film 30 may include oxygen in a content of about 25 atom % to about 40 atom %.

In this case, the light-shielding film 30 may have sufficient extinction properties.

As shown in FIG. 8, the light-shielding film 30 may include a first light-shielding layer 31 and a second light-shielding layer 32. Both the first and second light-shielding layers 31 and 32 may include a transition metal and at least one of oxygen and nitrogen.

The second light-shielding layer 32 may include a transition metal in a content of about 50 at % to about 80 at %. The second light-shielding layer 32 may include a transition metal in a content of about 55 at % to about 75 at %. The second light-shielding layer 32 may include a transition metal in a content of about 60 at % to about 70 at %. In the second light-shielding layer 32, the sum of the oxygen content and the nitrogen content may be about 10 at % to about 30 at %. In the second light-shielding layer 32, the sum of the oxygen content and the nitrogen content may be about 15 at % to about 25 at %. The second light-shielding layer 32 may include nitrogen in a content of about 5 at % to about 15 at %. The second light-shielding layer 32 may include nitrogen in a content of about 7 at % to about 13 at %.

The first light-shielding layer 31 may include a transition metal in a content of about 30 at % to about 60 at %. The first light-shielding layer 31 may include a transition metal in a content of about 35 at % to about 55 at %. The first light-shielding layer 31 may include a transition metal in a content of about 40 at % to about 50 at %. In the first light-shielding layer 31, the sum of the oxygen content and the nitrogen content may be about 40 at % to about 70 at %. In the first light-shielding layer 31, the sum of the oxygen content and the nitrogen content may be about 45 at % to about 65 at %. In the first light-shielding layer 31, the sum of the oxygen content and the nitrogen content may be about 50 at % to about 60 at %. The first light-shielding layer 31 may include oxygen in a content of about 20 at % to about 37 at %. The first light-shielding layer 31 may include oxygen in a content of about 23 at % to about 33 at %. The first light-shielding layer 31 may include oxygen in a content of about 25 at % to about 30 at %. The first light-shielding layer 31 may include nitrogen in a content of about 20 at % to about 35 at %. The first light-shielding layer 31 may include nitrogen in a content of about 26 at % to about 33 at %. The first light-shielding layer 31 may include nitrogen in a content of about 26 at % to about 30 at %.

The transition metal may include at least one of Cr, Ta, Ti and Hf. The transition metal may be Cr.

In this case, the first light-shielding layer 31 may help the light-shielding film 30 have excellent extinction properties.

The thickness of the first light-shielding layer 31 may be about 250 Å to about 650 Å. The thickness of the first light-shielding layer 31 may be about 350 Å to about 600 Å. The thickness of the first light-shielding layer 31 may be about 400 Å to about 550 Å. In this case, the first light-shielding layer 31 may help the light-shielding film 30 effectively block exposure light.

The thickness of the second light-shielding layer 32 may be about 30 Å to about 200 Å. The thickness of the second light-shielding layer 32 may be about 30 Å to about 100 Å. The thickness of the second light-shielding layer 32 may be about 40 Å to about 80 Å. In this case, the second light-shielding layer 32 may improve the extinction characteristics of the light-shielding film 30 and may help to more precisely control the side surface profile of a light-shielding pattern film 35 formed during patterning of the light-shielding film 30.

A ratio of the thickness of the second light-shielding layer 32 to the thickness of the first light-shielding layer 31 may be about 0.05 to about 0.3. The ratio of the thickness of the second light-shielding layer 32 to the thickness of the first light-shielding layer 31 may be about 0.07 to about 0.25. The ratio of the thickness of the second light-shielding layer 32 to the thickness of the first light-shielding layer 31 may be about 0.1 to about 0.2.

In this case, the light-shielding film 30 has sufficient extinction characteristics and may more precisely control the side surface profile of a light-shielding pattern film 35 formed during patterning of the light-shielding film 30.

The content of a transition metal in the second light-shielding layer 32 may be larger than the content of a transition metal in the first light-shielding layer 31.

To more precisely control the side surface profile of the light-shielding pattern film 35 formed by pattering the light-shielding film 30 and to ensure that the reflectance of the surface of the light-shielding film 30 for inspection light in defect inspection has a value suitable for inspection, the second light-shielding layer 32 may be required to have a larger transition metal content than the first light-shielding layer 31.

In this case, recovery, recrystallization, and grain growth may occur in a transition metal contained in the second light-shielding layer 32 during the heat treatment of the formed light-shielding film 30. If grain growth occurs in the second light-shielding layer 32 containing a high content of a transition metal, the illuminance characteristics of the surface of the light-shielding film 30 may excessively change due to excessively grown transition metal particles. This may cause an increase in the number of pseudo defects detected when defects on the surface of the light-shielding film 30 are inspected with high sensitivity.

The light-shielding film 30, may have a transmittance of about 1% to about 2% for light with a wavelength of 193 nm. The light-shielding film 30 may have a transmittance of about 1.3% to about 2% for light with a wavelength of 193 nm. The light-shielding film 30 may have a transmittance of about 1.4% to about 2% for light with a wavelength of 193 nm.

The light-shielding film 30 may have an optical density of about 1.8 to about 3. The light-shielding film 30 may have an optical density of about 1.9 to about 3.

In this case, a thin film containing the light-shielding film 30 may effectively suppress the transmission of exposure light.

As shown in FIG. 9, the optical substrate 10 may further include the phase shift film 40.

The phase shift film 40 may be disposed between the light-transmissive substrate 20 and the light-shielding film 30. The phase shift film 40 may be a thin film that attenuates the light intensity of penetrating exposure light and adjusts a phase difference to substantially suppress the diffracted light occurring at the edge of a pattern.

The phase shift film 40 may have a phase difference of about 170° to about 190° for light with a wavelength of 193 nm. The phase shift film 40 may have a phase difference of about 175° to about 185° for light with a wavelength of 193 nm.

The phase shift film 40 may have a transmittance of about 3% to about 10% for light with a wavelength of 193 nm. The phase shift film 40 may have a transmittance of about 4% to about 8% for light with a wavelength of 193 nm. In this case, the resolution of a photomask 200 containing the phase shift film 40 may be improved.

The phase shift film 40 may include a transition metal and silicon. The phase shift film 40 may include a transition metal, silicon, oxygen and nitrogen. The transition metal may be molybdenum.

A hard mask may be placed on the light-shielding film 30. The hard mask may function as an etching mask film when etching the pattern of the light-shielding film 30. The hard mask may include silicon, nitrogen and oxygen.

A method of fabricating the optical substrate 10 includes a step of forming the light-shielding film 30 on the light-transmissive film. The light-shielding film 30 may be formed by a sputtering process.

After the sputtering process proceeds, a heat treatment process may proceed.

The heat treatment step may be performed at about 200° C. to about 400° C.

The heat treatment step may be performed for about 5 minutes to about 30 minutes.

In addition, the method of fabricating the optical substrate 10 may further include a step of cooling the light-shielding film 30 that has been subjected to the heat treatment process.

The sputtering target may be selected considering the composition of the light-shielding film 30 to be formed. The sputtering target may be applied with a single target containing a transition metal. The sputtering target may be applied with two or more targets including one target containing a transition metal. The target containing a transition metal may contain 90 atom % or more of a transition metal. The target containing a transition metal may contain 95 atom % or more of a transition metal. The target containing a transition metal may include 99 atom % of a transition metal.

The transition metal may include at least one of Cr, Ta, Ti and Hf. The transition metal may include Cr.

The atmospheric gas may include inert gas, reactive gas and sputtering gas. The inert gas does not contain elements constituting a formed thin film. The reactive gas contains elements constituting a formed thin film.

The sputtering gas ionizes in a plasma atmosphere and collides with a target. The inert gas may include helium.

The reactive gas may include a gas containing nitrogen element. The gas containing the nitrogen element may be, for example, N₂, NO, NO₂, N₂O, N₂O₃, N₂O₄, N₂O₅ or the like. The reactive gas may include a gas containing an oxygen element.

The gas containing the oxygen element may be, for example, O₂. The reactive gas may include a gas containing nitrogen element and a gas containing oxygen element. The reactive gas may include a gas containing both nitrogen element and oxygen element. The gas containing both the nitrogen element and the oxygen element may be, for example, NO, NO₂, N₂O, N₂O₃, N₂O₄, N₂O₅, or the like.

In addition, the reactive gas containing carbon and oxygen may be CO₂.

The sputtering gas may be Ar gas.

A power source that applies power to the sputtering target may be either DC power or RF power.

Next, the cooled light-shielding film 30 may be cleaned. The cleaning process may include an ultraviolet irradiation process and/or a rinse process.

The ultraviolet irradiation process may include a step of irradiating ultraviolet rays to the light-shielding film 30.

The rinse process includes a step of treating the light-shielding film 30 with a cleaning solution. The cleaning solution may include at least one of deionized water, hydrogen water, ozone water and carbonated water. The cleaning solution may include the carbonated water.

The optical substrate 10 may be disposed in the chamber 100. The optical substrate 10 may be temporarily fixed to the chuck 200. The optical substrate 10 may be disposed in the receiving part. The optical substrate 10 may be seated on the chuck 200.

The method of fabricating the blank mask according to an embodiment includes a step of forming a photoresist layer 50 on the optical substrate 10.

To form the photoresist layer 50, the inside of the chamber 100 is isolated from the outside by a cover of the chamber 100. Next, in a state where the chuck 200 rotates at high speed, the photoresist resin composition is dropped and coated on the top surface of the optical substrate 10 by the photoresist resin composition supply part 500. Accordingly, a photoresist resin composition layer may be formed on the optical substrate 10.

The method of fabricating the blank mask according to an embodiment includes a step of discharging the process by-products 511, generated from a space between the side surface 12 of the optical substrate 10 and the chuck 200, by vacuum pressure in the process of forming the photoresist layer 50.

When the photoresist resin composition is coated on the optical substrate 10, the vacuum part 300 may apply vacuum pressure to the by-product removal part 230. Accordingly, the process by-products 511 may be removed from the space 250 between the side surface 12 of the optical substrate 10 and the chuck 200. That is, the process by-products 511 may be suctioned into the by-product removal part 230 from the space 250 between the side surface 12 of the optical substrate 10 and the guide part 220.

The step of removing the process by-products 511 and the step of rotating the optical substrate 10 at high speed by the chuck 200 may be performed at the same time. That is, the process of forming the photoresist layer 50 and the process of discharging the process by-products 511 may be performed at the same time.

The photoresist resin composition may include a binder resin, a photosensitizer and an organic solvent.

Examples of the binder resin include novolac resin, phenolic resin, epoxy resin, polyimide resin, and the like. Examples of the binder resin include polyvinyl pyrrolidone, poly(acrylamide-co-diacetoneacrylamide), and the like.

The photosensitizer may be selected from the group consisting of 4,4′-diazido-2,2′-stilbendisulfonate sodium salt, 4,4′-diazo-2,2′-dibenzalacetone disulfonate disodium salt, 2,5-bis(4-azido-2-sulfobenzylidene)cyclopentanone disodium salt and 4,4′-diazido-2,2′-stilbendisulfonate sodium salt.

The solvent may be selected from the group consisting of ethyl acetate, butyl acetate, diethylene glycol dimethyl ether, diethylene glycol dimethyl ethyl ether, dipropylene glycol dimethyl ether, methyl methoxypropionate, ethyl ethoxy propionate (EEP), ethyl lactate, propylene glycol methyl ether acetate (PGMEA), propylene glycol methyl ether, propylene glycol propyl ether, methyl cellosolve acetate, ethyl cellosolve acetate, diethylene glycol methyl acetate, diethylene glycol ethyl acetate, acetone, methyl isobutyl ketone, cyclohexanone, dimethylformamide (DMF), N,N-dimethylacetamide (DMac), N-methyl-2-pyrrolidone (NMP), γ-butyrolactone, diethyl ether, ethylene glycol dimethyl ether, diglyme, tetrahydrofuran (THF), methanol, ethanol, propanol, iso-propanol, methyl cellosolve, ethyl cellosolve, diethylene glycol methyl ether, diethylene glycol ethyl ether, dipropylene glycol methyl ether, toluene, xylene, hexane, heptane and octane.

The photoresist resin composition may include about 3 wt % to about 50 wt % of the binder resin, about 2 wt % to about 40 wt % of the photosensitizer, and about 10 wt % to about 94 wt % of the solvent.

The photoresist resin composition may further include an additive such as a leveling agent or an adhesion aid.

Accordingly, the photoresist resin composition layer formed on the optical substrate 10 is dried, and the solvent is removed. Accordingly, the photoresist layer 50 may be formed on the optical substrate 10 as shown in FIG. 10. Accordingly, a blank mask 1 including the optical substrate 10 and the photoresist layer 50 may be fabricated.

Light is selectively irradiated to the photoresist layer 50, and the light-shielding film is selectively etched, thereby forming the light-shielding pattern film 35. Accordingly, a photomask 2 including the light-transmissive substrate 20 and the light-shielding pattern film 35 disposed on the light-transmissive substrate 20 may be formed as shown in FIG. 11.

The light-shielding pattern film 35 includes a transition metal and at least one of oxygen and nitrogen.

The light-shielding pattern film 35 may be formed by patterning the light-shielding film 30 of the blank mask 1 as described above.

Descriptions of the physical properties, composition and structure of the light-shielding pattern film 35 are omitted as they overlap with the descriptions of the light-shielding film 30 of the blank mask 1.

A method of fabricating a semiconductor device according to an embodiment includes a step of placing a light source, a photomask 2 and a semiconductor wafer coated with a resist film; an exposure step of selectively transmitting and emitting light, incident from the light source, onto a semiconductor wafer through the photomask 2; and a development step of developing a pattern on the semiconductor wafer.

The photomask 2 includes the light-transmissive substrate 20; and the light-shielding pattern film 35 disposed on the light-transmissive substrate 20.

The light-shielding pattern film 35 includes a transition metal and at least one of oxygen, nitrogen and carbon.

In the preparation step, the light source is a device capable of generating short-wavelength exposure light. The exposure light may be light having a wavelength of 200 nm. The exposure light may be arf light having a wavelength of 193 nm.

A lens may be additionally disposed between the photomask 2 and the semiconductor wafer. The lens has the function of reducing the circuit pattern shape on the photomask 2 and transferring it onto the semiconductor wafer. The lens is not limited as long as it can be generally applied to an Arf semiconductor wafer exposure process. For example, the lens may be a lens made of calcium fluoride (CaF₂).

In the exposure step, exposure light may be selectively transmitted onto the semiconductor wafer through the photomask 2. In this case, chemical degeneration may occur in a resist film part on which exposure light is incident.

In the development step, the semiconductor wafer that has been subjected to the exposure step may be treated with a developing solution to develop a pattern on the semiconductor wafer. When the applied resist film is a positive resist, a resist film part on which exposure light is incident may be dissolved by the developing solution. When the applied resist film is a negative resist, a resist film part on which exposure light is not incident may be dissolved by the developing solution. The resist film is formed into a resist pattern by treatment with the developing solution. A pattern may be formed on the semiconductor wafer using the resist pattern as a mask.

A description of the photomask 2 is omitted as it overlaps with the previous content.

The apparatus for fabricating a blank mask according to an embodiment includes the by-product removal part 230 disposed under a space between the guide part 220 and the side surface 12 of the optical substrate 10. The by-product removal part 230 may remove the process by-products 511 flowing into a space between the guide part 220 and the side surface 12 of the optical substrate 10.

In particular, the by-product removal part 230 may suction the process by-products 511 through vacuum pressure. Accordingly, the by-product removal part 230 may easily remove fine particle-type byproduct flowing between the guide part 220 and the side surface 12 of the optical substrate 10.

In particular, the by-product removal part 230 is disposed to correspond to a corner where the side surface 12 of the optical substrate 10 and the lower surface 13 thereof meet, thereby efficiently removing the process by-products 511.

Accordingly, the apparatus for fabricating a blank mask according to an embodiment may minimize contamination by the process by-products 511. In particular, the blank mask according to an embodiment may prevent the process by-products 511 from contaminating the side surface 12 of the optical substrate 10 and the lower surface 13 thereof.

Although the preferred embodiments of the present invention have been described in detail above, the scope of the present invention is not limited thereto, and various modifications and improvements made by those skilled in the art using the basic concept of the present invention defined in the accompanying claims are also within the scope of the present invention.

### DESCRIPTION OF SYMBOLS

chamber 100
chuck 200
vacuum part 300
exhaust part 400
photoresist resin composition supply part 500

What is claimed is:

1. An apparatus for fabricating a blank mask, the apparatus comprising:
a chamber; and
a rotatable chuck placed inside the chamber,
wherein the rotatable chuck comprises:
a support part configured to support an optical substrate placed on the support part; and
a guide part disposed on a side of the optical substrate and connected to the support part,
wherein an interval between the guide part and a side surface of the optical substrate is greater than 0 mm and less than 1 mm.

2. The apparatus according to claim 1, further comprising a by-product removal part disposed in a space between the side surface of the optical substrate and the guide part and configured to remove process by-products flowing into the space between the side surface of the optical substrate and the guide part.

3. The apparatus according to claim 2, further comprising a vacuum part for applying vacuum pressure to the by-product removal part, when the by-product removal part suctions the process by-products.

4. The apparatus according to claim 3, wherein the by-product removal part comprises a plurality of spaced apart holes for suctioning the process by-products when the holes are connected to the vacuum part.

5. The apparatus according to claim 4, wherein the holes have a diameter of about 0.5 mm to about 2 mm, and an interval between the holes is about 10 mm to 100 mm, and wherein the holes are disposed at an edge of the support part disposed in the space between the side surface of the optical substrate and the guide part.

6. The apparatus according to claim 1, wherein a height difference between a top surface of the guide part and a top surface of the optical substrate when the optical substrate is positioned on the support part is less than 1 mm.

7. The apparatus according to claim 2, wherein the by-product removal part is disposed to correspond to a corner region where the side surface of the optical substrate and a lower surface of the optical substrate meet.

8. The apparatus according to claim 2, wherein the by-product removal part suctions the process by-products and discharges the process by-products outside of the chamber.

9. A method of fabricating a blank mask, the method comprising:
forming an optical substrate comprising a light-shielding film on a light transmissive substrate;
seating a chuck on the optical substrate comprising the light-shielding film formed thereon;
forming a photoresist layer on the light-shielding film; and
removing process by-products, generated in the process of forming the photoresist layer, from a space between a side surface of the optical substrate and the chuck.

10. The method according to claim 9, wherein the forming of the photoresist layer comprises:
dropping a photoresist composition on the light-shielding film; and
rotating the optical substrate,
wherein the rotating of the optical substrate is performed simultaneously with the removing of the process by-products.

11. The method according to claim 10, wherein the chuck comprises:
a support part disposed under the optical substrate;
a guide part connected to the support part and disposed on a side of the optical substrate; and
a by-product removal part configured to suction and discharge process by-products by vacuum pressure.

12. The method according to claim 11, wherein the process by-products are fine particles derived from the photoresist resin composition, and
wherein the by-product removal part is disposed at an edge region of a receiving part of the support part adjacent to an edge region of the optical substrate.

13. The method according to claim 12, wherein the fine particles have a diameter of about 1 to about 10 μm.

14. The method according to claim 11, wherein the optical substrate rotates at a speed of about 500 rpm to about 7000 rpm, and
wherein an exhaust speed of the by-product removal part is about 1 ml/s to about 100 ml/s.

15. The method according to claim 11, wherein an interval between the guide part and the side surface of the optical substrate is greater than 0 mm and less than 1 mm.

16. The method according to claim 15, wherein the by-product removal part comprises holes configured to penetrate the chuck and to connect with a vacuum part.

17. The method according to claim 16, wherein the holes have a diameter of about 0.5 mm to about 2 mm, and an interval between the holes is about 10 mm to 100 mm.

18. The method according to claim 16, wherein the vacuum pressure is applied by the vacuum part connected to the holes, and
the vacuum part discharges the process by-products flowing through the holes.

19. The method according to claim 11, wherein a top surface of the optical substrate is higher than a top surface of the guide part,
wherein a height difference between the top surface of the guide part and the top surface of the optical substrate is about 0.1 mm to about 0.5 mm.

20. An apparatus for fabricating a blank mask, the apparatus comprising:
a vacuum sealed chamber; and
a rotatable chuck placed in a vacuum sealing arrangement inside the chamber, the chuck comprising a support part and a guide part connected to the support part, the support part and the guide part forming a receiving part configured to receive an optical substrate leaving an interval between the guide part and a side surface of the optical substrate of greater than 0 mm and less than 1 mm, wherein the support part extends both inside and outside of the chamber,
a plurality of holes formed in the support part in a space between the side surface of the optical substrate and the guide part and configured to remove process by-products flowing into the space between the side surface of the optical substrate and the guide part, and
a vacuum part for applying vacuum pressure to the plurality of holes for suctioning and discharging the process by-products.

21. The apparatus according to claim 2, wherein the by-product removal part is disposed at an edge region of a receiving part of the support part adjacent to an edge region of the optical substrate.
